(19) United States
(12) Patent Application Publication
(10) Pub. No.: US 2011/0232940 A1
(43) Pub. Date: Sep. 29, 2011

(54) LOW IONIZATION POTENTIAL ADDITIVE TO DIELECTRIC COMPOSITIONS

(75) Inventors: Jae-Won George Hwang, Cambridge, MA (US); Jeffrey H. Lang, Sudbury, MA (US); Markus Zahn, Lexington, MA (US)

(73) Assignee: Massachusetts Institute of Technology, Cambridge, MA (US)

(21) Appl. No.: 13/070,198

(22) Filed: Mar. 23, 2011

Related U.S. Application Data
(60) Provisional application No. 61/316,524, filed on Mar. 23, 2010.

(51) Int. Cl. H05K 5/00; H01B 3/20; H01B 1/22; B82Y 30/00

(52) U.S. Cl. 174/17 LF; 252/579; 252/500; 252/519.3; 252/512; 977/785

(57) ABSTRACT

Insulating liquid. The liquid includes an ester liquid and an additive to the ester liquid having a lower ionization potential than the ionization potential of the ester liquid. In one aspect, conductive nanoparticles are also added.

### RELATED APPLICATION

This application claims the benefit of U.S. Provisional Application No. 61/316,524, filed on Mar. 23, 2010.

The entire teachings of the above application are incorporated herein by reference.

### BACKGROUND OF THE INVENTION

This invention relates to dielectric liquids for use in high voltage transformers, oil-insulated cables, and other oil-insulated high voltage devices.

The majority of high voltage components, such as paper insulated oil impregnated cables and high voltage power transformers in use today rely on mineral oil, also called transformer oil, as a vital piece of their electrical insulation system [I, 2]. The numbers in brackets refer to the references appended hereto. The contents of all of these references are incorporated by reference herein. The widespread use of transformer oils for high voltage insulation and power apparatus cooling is due to their greater electrical breakdown strength and thermal conductivity than gaseous insulators, while their ability to conform to complex geometries and self-heal means that they are often of more practical use than solid insulators. As such, the electrical insulation strength and characteristics of transformer oil has become the de facto standard for high voltage liquid insulation.

Due to the major implications which an insulation failure in electric power apparatus can have, scientists and engineers have for many years studied the insulating properties of dielectric liquids, particularly transformer oils, with a view to understanding the mechanisms behind electrical breakdown in an effort to reduce their likelihood [1]. Much of their work has focused on the formation of electrical streamers.

These are low density conductive structures that form in regions of oil that are over-stressed by electric fields on the order of 1×10⁸ V/m or greater [10]. Once a streamer forms it tends to elongate, growing from the point of initiation towards a grounding point. The extent of a streamer's development and velocity depends upon the nature of the electrical excitation (i.e., magnitude, duration, rise time, etc.) which caused it. Sustained over-excitation can result in a streamer short circuiting the oil gap between electrodes. When this happens an arc will form and electrical breakdown will occur.

The important role which streamers play in the electrical breakdown of dielectric liquids has meant that they have been the subject of significant scientific investigation. Much of the research on streamers in dielectric liquids has been empirical in nature and has led to the formation of a large literature on the subject of which the references [1, 7-19] are representative.

Within the past decade there has been considerable interest in finding a green, environmentally friendly replacement for transformer oil. In particular, much of the work has focused on vegetable-based oils composed of natural or synthetic esters [3-6] that are biodegradable. Unfortunately, ester liquids have been shown to have electrical insulation characteristics that greatly differ from transformer oil at extremely high voltages [4-6]. While ester liquids have similar breakdown voltage V_{b} (50% probability) as transformer oil, their breakdown time delay (i.e., the time between voltage application and breakdown) at slightly higher applied voltages in lightning impulse tests are extremely short or conversely the average streamer propagation velocity is very high (>>10 km/s) [4-6]. This differs from transformer oil where above its breakdown voltage V_{b} the average streamer velocity is low (i.e., 1-5 km/s) over a wide voltage range [6-9]. For example, it has been experimentally recorded in the literature that streamers in transformer oil travel 1-5 km/s for an applied voltage Vapp that ranges between V_{b}<Vₐₚₚ<2V_{b} [7, 9]. Above a certain voltage, called the acceleration voltage Vₐ, the streamer in transformer oil accelerates and travels at average velocities greater than 10 km/s [7].

For ester liquids to be considered as a viable replacement to transformer oils, their electrical insulating strength at high voltages must be improved. Specifically, their transition to fast streamer velocities (>10 km/s) must be pushed to higher voltages such that the time to breakdown is increased, which is significant because a slower streamer requires more time to traverse the liquid gap between electrodes to cause breakdown. This allows more time for the applied impulse voltage to be extinguished.

The work by Lesaint and Jung [32] with cyclohexane with a pyrene additive has shown that the addition of low ionization potential additives to these materials will create a space charge shielding effect whereby the additives will ionize and create a slow 2^{nd} mode streamer at a lower inception voltage. The creation of these streamers and their associated space charge shield the higher applied lightning impulse voltage levels and regulate the electric field enhancement at the streamer tip. Therefore, a greater applied voltage is needed to generate fast traveling streamers such as 3^{rd} and 4^{th} mode streamers such that the acceleration voltage occurs at high voltages in these non-ester liquids.

### SUMMARY OF THE INVENTION

The insulating liquid, or dielectric composition, according to the invention includes an ester liquid or water, and an additive to the ester liquid having a lower ionization potential than the ionization potential of the ester liquid. The ester liquid can further include vegetable oil, animal oil, mineral oil, and synthetic oil. In a preferred embodiment, the ester liquid is rapeseed oil, and a suitable additive is pinoresinol. Other suitable esters are sunflower, soybean, corn, cottonseed and sesame oils. Other suitable additives for use with the ester liquids are low ionization potential phenolic compounds such as 1-acetoxypinoresinol.

In another aspect, the insulating liquid, or dielectric composition, includes the further addition of conducting nanoparticles to offset the lower breakdown voltage caused by the addition of the low ionization potential additive.

In another aspect, the invention can be an electrical device that includes a housing, at least two electrodes, and a dielectric fluid contained within the housing, wherein the dielectric fluid includes an ester liquid and an additive having a lower ionization potential than the ionization potential of the ester liquid. In another aspect, the insulating liquid, or dielectric composition, includes the further addition of conducting nanoparticles to offset the lower breakdown voltage caused by the addition of the low ionization potential additive.

In another aspect, the invention can be a method of preparing a dielectric fluid. The steps of the method include combining an additive with a solution of an ester liquid, wherein the additive has an ionization potential lower than the ionization potential of the ester liquid.

This invention has many advantages. For example, the invention can increase the acceleration voltage of a dielectric fluid. As another example, the invention can increase both the acceleration voltage and the breakdown voltage of a dielectric fluid. Increasing the acceleration and breakdown voltage of a dielectric fluid can reduce the formation of electrical streamers in a dielectric fluid by increasing the inception voltage at which electrical streamers form. In particular, the invention can reduce the formation of fast electrical streamers. The inception voltage for fast streamers of vegetable-based oils composed of natural or synthetic esters can be increased by adding low ionization potential additives in small concentrations that inhibit fast streamers by space charge shielding at the high voltage electrode. Therefore, the invention can provide a more environmentally friendly insulating material for use in an electrical power apparatus than transformer oil while at the same time reducing the likelihood of electrical failure or other catastrophic event.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1a is a graph of stopping length versus applied voltage in rapeseed oil comprising natural esters as described in References 4, 5, and 34.

FIG. 1b is a graph of average velocity versus applied voltage in rapeseed oil as described in References 4, 5, and 34.

FIG. 1c is a graph of streamer charge versus applied voltage in rapeseed oil as described in References 4, 5, and 34.

FIG. 2 is a graph of average streamer velocity versus voltage in natural and synthetic esters and transformer oil as described in Reference 6.

### DETAILED DESCRIPTION OF THE INVENTION

A description of example embodiments of the invention follows.

While this invention has been particularly shown and described with references to example embodiments thereof, it will be understood by those skilled in the art that various changes in form and details may be made therein without departing from the scope of the invention encompassed by the appended claims.

Ester liquids, whether natural or synthetic, have pre-breakdown characteristics that are extremely different from transformer oil. This should not come as a surprise as esters have very different chemical compositions than transformer oil.

As in transformer oil, the onset of the streamer modes in ester liquids is dependent on the magnitude of the voltage excitation. Once again, the 2^{nd} mode initiates at the breakdown voltage V_{b} which denotes 50% probability of breakdown, while the 3^{rd} mode initiates at the acceleration voltage Vₐ where the streamer propagation velocity rises dramatically [7]. The 2^{nd}, 3^{rd}, and 4^{th} modes have velocities on the order of 1 km/s, 10 km/s, and 100 km/s, like in transformer oil [4-6]. Furthermore, the breakdown voltage V_{b} of ester liquids and transformer oil, where 2^{nd} mode streamers initiate, has been shown to be very close in magnitude for the same experimental setup [4-6].

The key difference between ester liquids and transformer oil is the acceleration voltage Vₐ level where streamers transition to very fast 3^{rd} and 4^{th} mode streamers. For transformer oil the acceleration voltage is much higher than the breakdown voltage. Therefore, in transformer oil the applied voltage range, where the slower 2^{nd} mode streamers dominate, is large and the voltage at which the dangerous 3^{rd} and 4^{th} mode streamers propagate is pushed to exceedingly high voltages. This ensures a lower probability for propagation of fast streamers that quickly traverse the oil gap to the counter electrode causing electrical breakdown before the applied voltage impulse can be extinguished.

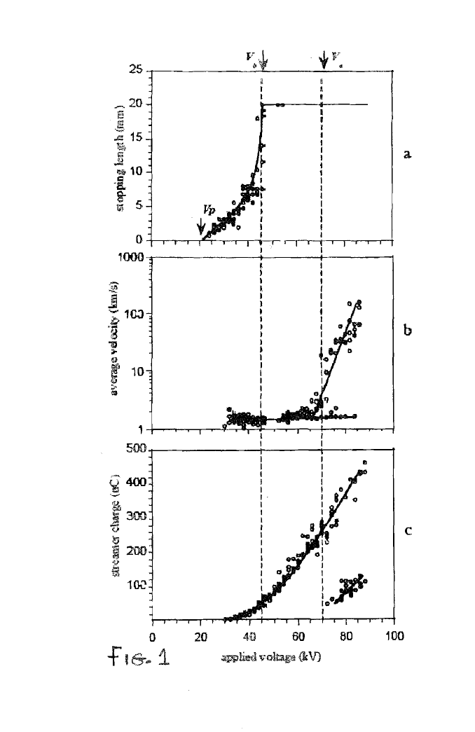

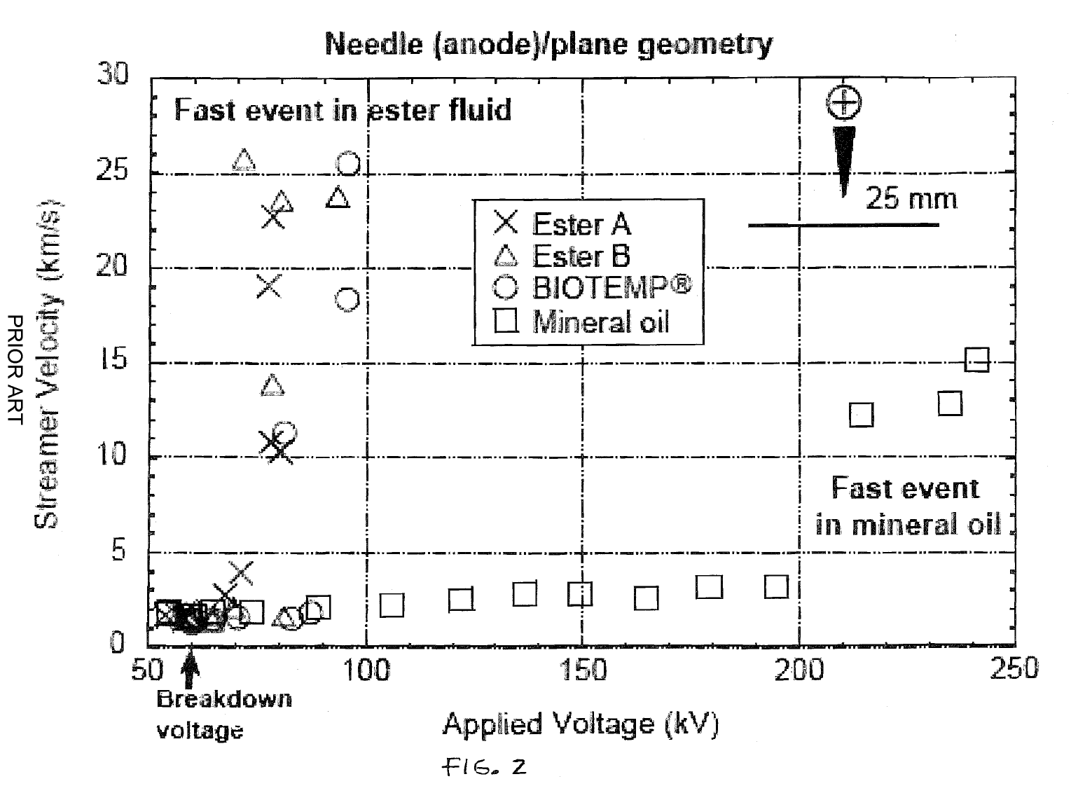

For ester liquids, the acceleration voltage Vₐ occurs almost directly above the breakdown voltage as shown by the two different experimental results from Duy et al. [4, 5, 34] and ABB [6] in FIGS. 1 and 2. Therefore, when the breakdown voltage is reached the streamers easily transition to streamers that propagate at average velocities greater than 10 km/s since V_{b}˜Vₐ for ester liquids and are not well-suited to insulate high-voltage systems.

According to the invention, the acceleration voltage of a pure ester liquid such as rapeseed oil is increased by adding a secondary molecule in low concentrations. The secondary molecule has an ionization potential that is lower than the main family of molecules comprising the ester liquid.

Many ester liquids are largely composed of oleic acid which has an ionization potential of 8.6 eV. Thus, additives such as pinoresinol with an ionization potential of 6.6 eV and other low ionization potential phenolic compounds such as 1-acetoxypinoresinol with an ionization potential of 6.8 eV are suitable additives according to some embodiments of the invention.

While the acceleration voltage Vₐ of esters is increased by adding the lower ionization potential additive according to this aspect of the invention, the breakdown voltage V_{b} is decreased. This lower breakdown strength of an insulating dielectric liquid due to the addition of a low ionization potential additive can be offset by the further addition of conducting nanoparticles of typical diameter around 10 nm, that raises the breakdown strength of a dielectric liquid and decreases positive streamer velocity [37,38]. This breakdown strength increase is due to the conversion of fast electrons produced by ionization of the dielectric liquids to slow negatively charged nanoparticle charge carriers with effective mobility reduction by a factor of about 10⁵ [38]. This also raises the acceleration voltage. Therefore, the use of conducting nanoparticles together with a low ionization potential additive can result in both an increased breakdown voltage for slow 2^{nd} mode streamers and an increased acceleration voltage for fast 3^{rd} and 4^{th} mode streamers.

### Example One

### Prophetic Example

A mixture of rapeseed oil and pinoresinol can be prepared by adding pinoresinol to rapeseed oil. The concentration of the pinoresinol additive can be about five percent by volume of the rapeseed oil. The breakdown voltage of the mixture is slightly decreased while the acceleration voltage is increased as compared to pure rapeseed oil. An acceptable range of concentration for the additive is about 3% to about 10% by volume. Other suitable esters are sunflower oil, soybean oil, corn oil, cottonseed oil and sesame oil, and other suitable additives are low ionization potential phenolic compounds such as 1-acetoxypinoresinol.

### Example Two

### Prophetic Example

A mixture of rapeseed oil and pinoresinol can be prepared by adding pinoresinol to rapeseed oil. The concentration of the pinoresinol additive can be about five percent by volume of the rapeseed oil. Magnetite nanoparticles having a dielectric relaxation time of about 10⁻¹⁴ seconds and sized about 10 nm in diameter can be added to the mixture of rapeseed oil and pinoresinol at a concentration about 10²⁰ nanoparticles/m³. The breakdown voltage and acceleration voltage of the mixture is increased as compared to pure rapeseed oil. An acceptable range of concentration for the pinoresinol additive is about 3% to about 10% by volume. Other suitable esters are sunflower oil, soybean oil, corn oil, cottonseed oil and sesame oil, and other suitable additives are low ionization potential phenolic compounds such as 1-acetoxypinoresinol. Other suitable nanoparticles can be any material with dielectric relaxation time less than about 50 microseconds, such as any iron oxide, zinc oxide, aluminum, copper, steel, titanium, or any metal or conducting material whose dielectric relaxation time is shorter than about 50 microseconds.

It is recognized that modifications and variations of the invention will be apparent to those of ordinary skill in the art and it is intended that all such modifications and variations be included within the scope of the appended claims.

### REFERENCES

[1] Beroual, M. Zahn, A. Badent, K. Kist, A. J. Schwabe, H. Yamashita, K. Yamazawa, M. Danikas, W. D. Chadband, and Y. Torshin, Propagation and structure of streamers in liquid dielectrics. IEEE Electr. Insul. Mag., 14(2):6-17, March 1998.
[2] A. Al-Sulaiman and M. I. Qureshi. The role of methylnaphthalene in ehv cable oil as related to oil breakdown and discharge velocity. European Transactions on Electrical Power, 12(6):389-395, November/December 2002.
[3] T. V. Oommen. Vegetable oils for liquid-filled transformers. 18(1):6-11, January 2002.
[4] C. T. Duy, O. Lesaint, N. Bonifaci, A. Denat, and Y. Bertrand. High voltage breakdown and pre-breakdown properties in rape-seed insulating oil. In Proc Annual Report—Conference on Electrical Insulation and Dielectric Phenomena CEIDP 2007, pp. 623-626, Oct. 14-17, 2007.
[5] C. T. Duy, O. Lesaint, A. Denat, N. Bonifaci, and Y. Bertrand. Streamer propagation and breakdown in rape-seed oil at high voltage. In Proc. IEEE International Conference on Dielectric Liquids ICDL 2008, pp. 1-4, June 2008.
[6] Rongsheng Liu, Christer Tornkvist, Yijaya Chandramouli, Orlando Girlanda, and Leif A. A. Pettersson. Ester fluids as alternative for mineral oil: the difference in streamer velocity and LI breakdown voltages. In Proc Annual Report Conference on Electrical Insulation and Dielectric Phenomena, 6 pages, Virginia Beach, Va., USA, October 2009.
[7] O. Lesaint and G. Massala. Positive streamer propagation in large oil gaps: experimental characterization of propagation modes. IEEE Trans. Dielectr. Electr. Insul., 5(3):360-370, June 1998.
[8] D. Linhjell, L. Lundgaard, and G. Berg. Streamer propagation under impulse voltage in long point-plane oil gaps. IEEE Trans. Electr. Insul., 1:447-458, 1994.
[9] L. Lundgaard, D. Linhjell, G. Berg, and S. Sigmond. Propagation of positive and negative streamers in oil with and without pressboard interfaces. IEEE Trans. Dielectr. Electr. Insul., 5(3):388-395, June 1998.
[10] R. Tobazeon. Prebreakdown phenomena in dielectric liquids. IEEE Trans. Dielectr. Electr. Insul., 1(6):1132-1147, December 1994.
[11] H. Akiyama. Streamer discharges in liquids and their applications. IEEE Trans. Dielectr. Electr. Insul., 7(5):646-653, October 2000.
[12] E. O. Forster. Critical assessment of the electrical breakdown process in dielectric fluids. IEEE Trans. Electr. Insul., (5):891-896, October 1985.
[13] R. E. Hebner. Measurements of electrical breakdown in liquids, pp. 519-537. Plenum Press, New York, 1988.
[14] Yu. V. Torshin. On the existence of leader discharges in mineral oil. IEEE Trans. Dielectr. Electr. Insul., 2(1): 167-179, February 1995.
[15] G. Massala and O. Lesaint. Positive streamer propagation in large oil gaps: electrical properties of streamers. IEEE Trans. Dielectr. Electr. Insul., 5(3):371-381, June 1998.
[16] Y. Nakao, T. Yamazaki, K. Miyagi, Y. Zakai, and H. Tagashira. The effect of molecular structure on prebreakdown phenomena in dielectric liquids under nonuniform field. Electrical Engineering in Japan, 139(2): 1-8, 2002.
[17] J. C. Devins, S. J. Rzad, and R. J. Schwabe. Breakdown and prebreakdown phenomena in liquids. J. Appl. Phys., 52: 4531-4545, 1981.
[18] W. G. Chadband. On variations in the propagation of positive discharges between transformer oil and silicone fluids. J. Phys. D: Appl. Phys., 13: 1299-1307, 1980.
[19] O. Lesaint and P. Gournay. Initiation and propagation thresholds of positive prebreakdown phenomena in hydrocarbon liquids. IEEE Trans. Dielectr. Electr. Insul., 1(4):702-708, August 1994.
[20] Nynas AB. Nynas Transformer Oil—Nytro 10XN (lEC 60296/03), 2008.
[21] L. Costeanu and O. Lesaint. On mechanisms involved in the propagation of subsonic positive streamers in cyclohexane. In Proc. IEEE 14th International Conference on Dielectric Liquids ICDL 2002, pp. 143-146, Graz, Austria, Jul. 7-12, 2002.
[22] CEI IIEC60897: 1987. Methods for the determination of the lightning impulse breakdown voltage of insulating liquids. lEC, Geneva, Switzerland, 1987.
[23] P. Biller. A simple qualitative model for the different types of streamers in dielectric liquids. In Proc. 12th International Conference on Conduction and Breakdown in Dielectric Liquids, ICDL '96, pp. 189-192, Baden-Dattwil, Switzerland, Jul. 15-19, 1996.
[24] M. Harada, Y. Ohga, I. Watanabe, and H. Watarai. Ionization energies for solvated polycyclic aromatic hydrocarbons. Chem. Phys. Lett., 303:489-492, 1999.
[25] H. S. Smalo, P.-O. Astrand, and S. Ingebrigtsen. Calculation of ionization potentials and electron affinities for molecules relevant for streamer initiation and propagation. In Proc. IEEE International Conference on Dielectric Liquids ICDL 2008, pp. 1-4, FuturoscopeChasseneuil, France, June 2008.
[26] D. R. Lide, editor. Physical Constants of Organic Compounds, pp. 519-537. CRC Press/Taylor and Francis, Boca Raton, 89th edition, 2009.
[27] J. George Hwang, Markus Zahn, Leif A. A. Pettersson, Olof Hjortstam, and Rongsheng Liu. Modeling streamers in transformer oil: The transitional fast 3rd mode streamer. In Proc. IEEE 9th International Conference on the Properties and Applications of Dielectric Materials ICPADM 2009, pp 573-578, Jul. 19-23, 2009.
[28] J. Nieto-Salazar, O. Lesaint, and A. Denat. Transient current and light emission associated to the propagation of pre-breakdown phenomena in water. In Proc Annual Report Electrical Insulation and Dielectric Phenomena Conference on, pp 542-545, 2003.
[29] J. Nieto-Salazar, N. Bonifaci, A. Denat, and O. Lesaint. Characterization and spectroscopic study of positive streamers in water. In Proc. IEEE International Conference on Dielectric Liquids ICDL 2005, pp. 91-94, 2005.
[30] F. M. J. McCluskey, O. Lesaint, and A. Denat. Breakdown processes over large distances in insulating liquids of distinct chemical compositions. In Conference Record of the 1994 IEEE International Symposium on Electrical Insulation, pp. 426-429, Jun. 5-8, 1994.
[31] F. M. J. McCluskey, A. Denat, and O. Lesaint. Breakdown and prebreakdown phenomena in liquids under positive impulse voltages. 1(3):377-382, June 1994.
[32] O. Lesaint and M. Jung. On the relationship between streamer branching and propagation in liquids: influence ofpyrene in cyclohexane. J. Phys. D: Appl. Phys., 33:1360-1368, 2000.
[33] F. M. O'Sullivan. A model for the initiation and propagation of electrical streamers in transformer oil and transformer oil based nanofluids. PhD thesis, Massachusetts Institute of Technology, 2007.
[34] C. T. Duy, O. Lesaint, A. Denat, and N. Bonifaci. Streamer propagation and breakdown in natural ester at high voltage. IEEE Trans. Dielectr. Electr. Insul., 16(6):1582-1594, December 2009.
[35] N. Nenadis, L.-F. Wang, M. Z. Tsimidou, and H.-Y. Zhang. Radical scavenging potential of phenolic compounds encountered in O. europaea products as indicated by calculation of bond dissociation enthalpy and ionization potential values. J. Agric. Food Chem., 53: 295-299, 2005.
[36] D. G. Nash, X. F. Liu, E. R. Mysak, and T. Baer. Aerosol particle mass spectrometry with low photon laser ionization. Int. J. Mass Spectrometry, 241: 89-97, 2005.
[37] U.S. Pat. No. 5,863,455, Jan. 26, 1999.
[38] J. G. Hwang, M. Zahn, F. O'Sullivan, L. A. A. Pettersson, O. Hjortstarm, and R. Liu, Effects of nanoparticle charging on streamer development in transformer oil-based nanofluids, Journal of Applied Physics, Volume 107, Issue 1, pp. 014310-014310-17 (2010)

What is claimed is:

1. A dielectric composition, comprising:
a) an ester liquid or water; and
b) an additive to the ester liquid having a lower ionization potential than the ionization potential of the ester liquid.

2. The dielectric composition according to claim 1, wherein the ester liquid further includes at least one member selected from the group consisting of vegetable oil, animal oil, mineral oil, and synthetic oil.

3. The dielectric composition according to claim 1, wherein the ester liquid includes rapeseed oil.

4. The dielectric composition according to claim 3, wherein the ester liquid consists essentially of rapeseed oil.

5. The dielectric composition according to claim 1, wherein the ester liquid includes at least one member of the group consisting of sunflower oil, soybean oil, corn oil, cottonseed oil and sesame oil.

6. The dielectric composition of claim 1, wherein the additive is at least one member selected from the group consisting of pinoresinol or 1-acetoxypinoresinol.

7. The dielectric composition of claim 6, wherein the additive is present at a final concentration in a range of between about 3% to about 10% by volume.

8. The dielectric composition of claim 6 wherein the additive is pinoresinol or 1-acetoxypinoresinol.

9. A dielectric composition, comprising:
a) an ester liquid;
b) an additive to the ester liquid having a lower ionization potential than the ionization potential of the ester liquid; and
c) a conductive nanoparticle additive.

10. The dielectric composition according to claim 9, wherein the ester liquid is selected from the group consisting of rapeseed oil, sunflower oil, soybean oil, corn oil, cottonseed oil and sesame oil.

11. The dielectric composition of claim 9 wherein the low ionization potential additive is pinoresinol or 1-acetoxypinoresinol.

12. The dielectric composition of claim 9 wherein the conductive nanoparticle additive is iron oxide (magnetite, Fe₃O₄).

13. The dielectric composition of claim 9 wherein the conductive nanoparticle additive is selected from the group consisting of any iron oxide, zinc oxide, aluminum, copper, steel, titanium, or any metal or conducting material whose dielectric relaxation time is shorter than about 50 microseconds.

14. The electrical device of claim 9 wherein the conductive nanoparticle additive has diameter of about 10 nm.

15. The dielectric composition of claim 9 wherein the conductive nanoparticle additive has diameter of about 10 nm.

16. An electrical device, comprising:
a) a housing;
b) at least two electrodes; and
c) a dielectric fluid contained within the housing, wherein the dielectric fluid includes an ester liquid and an additive having a lower ionization potential than the ionization potential of the ester liquid.

17. The electrical device of claim 16 wherein the ester liquid is a vegetable oil.

18. The electrical device of claim 16 wherein the ester liquid is rapeseed oil.

19. The electrical device of claim 16 wherein the ester liquid is selected from the group consisting of rapeseed oil, sunflower oil, soybean oil, cottonseed oil and sesame oil.

20. The electrical device of claim 16 wherein the additive is present at a final concentration in a range of between about 3% to about 10% by volume.

21. An electrical device, comprising:
a) a housing;
b) at least two electrodes; and
c) a dielectric fluid contained within the housing, wherein the dielectric fluid includes:
i) an ester liquid;
ii) an additive having a lower ionization potential than the ionization potential of the ester liquid; and
iii) a conducting nanoparticles additive.

22. The electrical device of claim 21 wherein the conductive nanoparticle additive is iron oxide (magnetite, Fe₃O₄).

23. The electrical device of claim 21 wherein the conductive nanoparticle additive is selected from the group consisting of any iron oxide, zinc oxide, aluminum, copper, steel, titanium, or any metal or conducting material whose dielectric relaxation time is shorter than about 50 microseconds.

24. The electrical device of claim 21 wherein the conductive nanoparticle additive has diameter of about 10 nm.

25. A method of preparing a dielectric fluid, comprising the step of:
a) combining an additive with a solution of an ester liquid, wherein the additive has an ionization potential lower than the ionization potential of the ester liquid.

26. The method of preparing the dielectric fluid of claim 25, wherein the additive is present at a final concentration in a range of between about 3% to about 10% by volume.

27. The method of preparing the dielectric fluid of claim 25, wherein the ester liquid includes a vegetable oil.

28. The dielectric composition of claim 25, wherein the additive is at least one member selected from the group consisting of pinoresinol or 1-acetoxypinoresinol.
